(19) United States
(12) Patent Application Publication
(10) Pub. No.: US 2019/0292383 A1
(43) Pub. Date: Sep. 26, 2019

(54) STRETCHABLE CONDUCTIVE PASTE COMPOSITION

(71) Applicant: E I DU PONT DE NEMOURS AND COMPANY, Wilmington, DE (US)

(72) Inventors: Jing Fan, Shanghai (CN); Fei Xiang, Shanghai (CN)

(21) Appl. No.: 16/466,368

(22) PCT Filed: Feb. 24, 2017
(86) PCT No.: PCT/CN2017/074710

§ 371 Date: Jun. 4, 2019

(51) Int. Cl. C09D 5/24; C09D 127/20; C09D 7/40; C09D 7/62; H01B 1/22; B32B 5/02

(52) U.S. Cl. CPC C09D 5/24; C09D 127/20; C09D 7/70; H05K 1/095; H01B 1/22; B32B 5/02; H05K 2201/0314; C09D 7/62

(57) ABSTRACT

This invention is related to a polymer thick film (PTF) paste composition comprising a conductive powder, an elastomer blend consisting of two or more elastomers at least one of which is a peroxide curable fluoroelastomer, and a solvent blend consisting of at least one solvent in which each of the elastomers of the elastomer blend is individually soluble and at least one solvent in which at least one of the elastomers of the elastomer blend is not individually soluble. The PTF paste composition can be used to form a printed conductor and to form an electrically conductive adhesive on various articles.

### FIELD OF THE INVENTION

This invention is directed to a stretchable conductive paste composition for wearables and in mold electronics.

### BACKGROUND OF THE INVENTION

There is increasing interest in incorporating electrical circuits in wearable garments to monitor physiological aspects of the wearer. Examples of such measurements include heart rate, electrocardiography, temperature and bodily fluids. These circuits must be maintained as the garment or article is stretched and when exposed to multiple wash and dry cycles. Another use for electrical circuits in wearable garments is in heaters.

In addition, there is a need for electrically conductive adhesives that can tolerate the stretching and deformation that occurs during thermoforming and injection molding processes for In Mold Electronics (IME).

### SUMMARY OF THE INVENTION

This invention relates to a stretchable polymer thick film paste composition that when used to form a printed conductor in a wearable garment, to form an electrically conductive adhesive for In Mold Electronics or to form a printed conductor for consumer electronics provides a stretchable polymer thick film.

The invention provides a polymer thick film paste composition comprising:
a) a conductive powder;
b) an elastomer blend consisting of two or more elastomers at least one of which is a peroxide curable fluoroelastomer; and
c) a solvent blend consisting of at least one solvent in which each of the elastomers of the elastomer blend is individually soluble and at least one solvent in which at least one of the elastomers of the elastomer blend is not individually soluble.

### DETAILED DESCRIPTION OF THE INVENTION

The invention relates to a polymer thick film (PTF) paste composition comprising a conductive powder, an elastomer blend consisting of two or more elastomers at least one of which is a peroxide curable fluoroelastomer, and a solvent blend consisting of at least one solvent in which each of the elastomers of the elastomer blend is individually soluble and at least one solvent in which at least one of the elastomers of the elastomer blend is not individually soluble. In an embodiment, the PTF paste composition further comprises one or more processing aids selected from the group consisting of a cross-linking agent, a cross-linking co-agent agent, an antioxidant, an adhesion promoter, a wetting agent, a defoaming agent and a rheology modifier

The PTF paste composition can be used to form printed conductors in various articles. The PTF paste composition can be used to form printed conductors that can be used in wearable garments. In one embodiment the conductor is printed directly on the garment fabric. In another embodiment the conductor is printed on a substrate which is then subsequently laminated to the garment. This stretchable printed conductor maintains its usefulness during the stretching and washing and drying that such a garment undergoes.

The PTF paste composition can also be used to form printed conductors and to form an electrically conductive adhesive for other articles. These articles can be thermoformed and subsequently subjected to injection molding and the printed conductor or electrically conductive adhesive tolerates the stretching and deformation that occurs during these processes.

The components of the PTF paste composition are discussed in more detail below. Weight percent is written as wt %.

### Conductive Powder

The conductive powder is an electrically conductive powder of one or more of Ag, Cu, Au, Pd, Pt, Sn, Al, Ni, C, alloys thereof and mixtures thereof.

In one embodiment the conductive powder is in the form of silver flakes. In another embodiment the conductive powder is in the form of silver flakes with a sodium oleate/stearate coating.

The amount of conductive powder in the PTF paste composition is 40-90 wt %, wherein the wt % is based on the total weight of the polymer thick film paste composition.

### Elastomer Blend

The elastomer blend consists of two or more elastomers.

In an embodiment the elastomer blend consists of two or more peroxide curable fluoroelastomers. In one embodiment, the two or more peroxide curable fluoroelastomers are peroxide curable vinylidene fluoride-containing fluoroelestomers copolymers. In one such embodiment, the two or more peroxide curable fluoroelastomers are peroxide curable vinylidene fluoride/hexafluoropropylene/tetrafluoroethlene terpolymers. The amount of the two or more peroxide curable fluoroelastomers is 3-30 wt %, wherein the wt % are based on the total weight of the polymer thick film paste composition.

In another embodiment, the elastomer blend consists of at least one peroxide curable fluoroelastomer and at least one other elastomer that is not a fluoroelastomer. In an embodiment, the at least one peroxide curable fluoroelastomer is a peroxide curable vinylidene fluoride-containing fluoroelastomer and the at least one other elastomer is an ethylene/methyl acrylate copolymer elastomer. The amount of the at least one peroxide curable fluoroelastomer is 2-30 wt % and the amount of ethylene/methyl acrylate copolymer elastomer is 0.1-10 wt %, wherein the composition. In one such embodiment, the at least one or more peroxide curable fluoroelastomers are peroxide curable vinylidene fluoride/hexafluoropropylene/tetrafluoroethlene terpolymers.

### Solvent Blend

The solvent blend consists of at least one solvent in which each of the elastomers of the elastomer blend is individually soluble and at least one solvent in which at least one of the elastomers of the elastomer blend is not individually soluble.

To determine whether a solvent is one in which each of the elastomers in the elastomer blend is individually soluble or is one in which at least one of the elastomers in the elastomer blend is not individually soluble, we use the Solubility Parameter (SP) method. In SP approach, the solubility parameter δ=(E/V)^{1/2}, the square root of the cohesive energy (pressure) E per unit volume V. The SI unit of δ is in MPa^{1/2}. The Solubility Parameter (SP) method provides a convenient and effective way in predicting compatibility between the solvents and the elastomers. Those with similar δT possibly showing good compatibility and miscibility.

The obtained δ is normally called the total solubility parameter (δT), and can be separated into 3 parameters that take into account the Dispersion (δD), the Polar (δP) and the Hydrogen Bonding (δH) effects: δT=(δD²+δP²+δH²)^{1/2}

According to <Hansen Solubility Parameters, 2^{nd} Edition> published by CRC Press, δT of Viton is 19.9, and all solvents used have δT close to 20 MPa^{1/2}. Since the fluoroelastomers in the elastomer blend are highly polar with little or no hydrogen bonding, when determining whether a solvent is one in which each of the elastomers in the elastomer blend is individually soluble or is one in which at least one of the elastomers in the elastomer blend is not individually soluble the focus is on the percent contribution of δD (fδD) and the percent contribution of δP (fδP).

The percent contribution calculations of δD, δP and δH are: fδD%=δD×100%/(δD+δP+δH); fδP%=δP×100%/(δD+δP+δH); fδH%=δH×100%/(δD+δP+FδH); fδD%+fδP%+fδH%=100%.

δD, δP and δH and fδD%, fδP% and fδH% are shown in Table 1 for an assortment of solvents.

TABLE I

| | Solvent | δT | δD | δP | δH | fδD % | fδP % | fδH % |
|---|---|---|---|---|---|---|---|---|
| 1st | Acetone | 20 | 15.5 | 10.4 | 7 | 47.1 | 31.6 | 21.3 |
| Sol- | MIBK | 17 | 15.3 | 6.1 | 4.1 | 60 | 23.9 | 16.1 |
| vent | DIBK | 16.9 | 16 | 3.7 | 4.1 | 67.2 | 15.6 | 17.2 |
| | Cyclo- | 19.6 | 17.8 | 6.3 | 5.1 | 61 | 21.5 | 17.5 |
| | hexanone | | | | | | | |
| | Methyl | 19 | 16 | 9 | 5.1 | 53.2 | 29.9 | 16.9 |
| | ethyl | | | | | | | |
| | ketone | | | | | | | |
| | Isophorone | 19.9 | 16.6 | 8.2 | 7.4 | 51.5 | 25.5 | 22.3 |
| | N-Methyl- | 22.9 | 18 | 12.3 | 7.2 | 48 | 32.8 | 19.2 |
| | 2-pyrrol- | | | | | | | |
| | idinone | | | | | | | |
| 2nd | C11 ketone | 16.4 | 15.8 | 2 | 4 | 72.5 | 9.2 | 18.3 |
| Sol- | Dibasic | 19.7 | 16.6 | 4.6 | 9.6 | 53.9 | 14.9 | 31.2 |
| vent | esters | | | | | | | |
| | ethylene | 23.4 | 16.4 | 10.5 | 12.9 | 41.2 | 26.4 | 32.4 |
| | glycol | | | | | | | |
| | diacetate | | | | | | | |
| | diethylene | 18.8 | 15.8 | 5 | 9 | 53 | 16.8 | 30.2 |
| | glycol | | | | | | | |
| | monoethyl | | | | | | | |
| | ether | | | | | | | |
| | acetate | | | | | | | |
| | diethylene | 18.4 | 16 | 4.1 | 8.2 | 56.5 | 14.5 | 29 |
| | glycol | | | | | | | |
| | monobutyl | | | | | | | |
| | ether | | | | | | | |
| | acetate | | | | | | | |
| | Diethylene | 20.4 | 16 | 7.0 | 10.6 | 47.7 | 20.8 | 31.5 |
| | Glycol | | | | | | | |
| | Monobutyl | | | | | | | |
| | Ether | | | | | | | |

The 1^{st} solvent group contains solvents in which each of the elastomers in the elastomer blend is individually soluble. The 2^{nd} solvent group contains solvents in which at least one of the elastomers in the elastomer blend is not individually soluble. The columns in Table 1 for fδD% and fδP% in Table 1 are bolded since these are used in the criteria for determining whether a solvent is one in which each of the elastomers in the elastomer blend is individually soluble or is one solvent only solve

The criteria used are fδD%+fδP%≥75% and fγP%≥15%. As used herein, if a solvent satisfies both of these criteria it is “a solvent in which each of the elastomers in the elastomer blend is individually soluble” and if a solvent does not satisfy both of these criteria it is “a solvent in which at least one of the elastomers in the elastomer blend is not individually soluble”

The amount of solvent in which each of the elastomers in the elastomer component is individually soluble is 1-20 wt % and the amount of solvent in which at least one of the elastomers is not individually soluble is 5-35 wt %, wherein the wt % are based on the total weight of the polymer thick film composition.

### EXAMPLES AND COMPARATIVE EXPERIMENTS

In each of the Examples and Comparative Experiments the PTF paste composition was prepared as follows. The elastomers and the processing aids were compounded in a two roll mill at room temperature for 20 minutes. The above as-made mixture was added to the solvent to form a first solution mixture to which was added the curing agent, adhesion promoter and Ag flakes to form a PTF paste composition.

To determine the volume resistivity of each PTF, the PTF paste composition was blade-casted on an insulating glass slide to form a 30×2 mm strip that was dried at 130° C. for 15 min in an oven.

The sheet resistance of the cured strips was measured by a four-probe method using a sheet resistivity meter QT-70/5601Y (manufactured by Quatek Co. Ltd., Taiwan) and the thickness of the cured strip was measured using a Dektal XT™ stylus profiler (manufactured by Bruker Corp., Germany).

The volume resistivity of the cured strips was calculated using the equation: ρ (Resistivity) sheet resistance×thickness×geometry correction=sheet resistance×thickness×1.9475/4.5324.

The PTF paste composition was also blade-casted over a Bemis ST604 thermoplastic polyurethane substrate and cured at 130° C. for 15 min in an oven for use in stretching and washing fatigue tests.

The dimension for the stretching fatigue test is 25 μm*1 cm*8 cm. The sample was stretched up to 40% strain and held for 25 s. Then the resistance was measured at that strain. The strain was released and the sample was allowed to recover to its original length, hold for 25 s, and the resistance at recovery measured. This was repeated for 50 cycles.

The dimension for the washing fatigue test is 25 μm*0.8 cm*10 cm. The washing cycle was carried out in a drum washing machine Little Swan TG80V20WDX. The sample was washed for 55 mins with additional 870 g fabric and 16 g detergent in 8 L city water. Drying cycle is carried out in an oven at 50° C. for 20 min. Resistance was measured before and after 5 wash and dry cycles to determine the change.

The components used in the Examples and the Comparative Experiments were:

FE-1: a vinylidene fluoride/hexafluoropropylene/tetrafluoroethylene terpolymer, Viton®GF200S (DuPont);

FE-2: a vinylidene fluoride/hexafluoropropylene/tetrafluoroethylene terpolymer, Viton®GBL200 (DuPont);

AEM: an ethylene acrylate dipolymer elastomer, Vamac® DP (DuPont);

MIBK: 4-Methyl-2-pentanone (Sinopharm Chemical Reagent Co., Ltd., China);

DIBK: 2,6-Dimethyl-4-heptanone (Sinopharm Chemical Reagent Co., Ltd., China);

C-11: C-11 ketone (DuPont);

TAIC: triallyl isocyanurate, Rhenofit® TAIC/S (Rhein Chemie)

BHT: butylated hydroxytoluene (Sinopharm Chemical Reagent Co., Ltd.

Antioxidant: 4,4′-bis(α,α-dimenthylbenzyl) diphenylamince, Naugurd™ 445 (Chemtura Corporation, U.S.A.);

MqO: magnesium oxide, (Kyowa Chemical Industry Co., Ltd., (Japan);

Adhesion promoter: γ-glycidylpropyltrimethoxysilane (Sinopharm Chemical Reagent Co., Ltd.);

Curing Agent: peroxide-based curing agent (1,1-di(t-butylperoxy)-3,3,5-trimethylcyclohexane) (Sinopharm Chemical Reagent Co., Ltd;)

Ag Flakes-1: Sodium oleate/stearate coating—D50 2.1-3.3 μm Ag Flakes-2: Sodium oleate/stearate coating—D50 2.1-3.3 μm

The amounts of components in weight percent used in Examples E1-E5 and Comparative Experiments CE1-CE4 are shown in Table II. The wt % are based on the total weight of the composition. Properties of each PTF made with the paste composition are also shown. The strips of the Examples show the advantage of the invention when compared with those of the Comparative Examples.

TABLE II

| | | | | | | | | |
|---|---|---|---|---|---|---|---|---|
| CE1 | CE2 | CE3 | CE4 | E1 | E2 | E3 | E4 | E5 |

COMPOSITION

| | | | | | | | | | |
|---|---|---|---|---|---|---|---|---|---|
| FE-1 | | 13.93 | 13.93 | 8.36 | 8.36 | 8.53 | 8.32 | 8.67 | 12.36 |
| FE-2 | 14.22 | | | 5.57 | 5.57 | 7.11 | 5.55 | 9.40 | 5.30 |
| AEM | 3.56 | 3.48 | 3.48 | 3.48 | 3.48 | 2.13 | 3.47 | | |
| MIBK | 6.95 | 6.99 | | 6.99 | | | | | |
| DIBK | 20.86 | 20.97 | 27.95 | 20.97 | 6.99 | 6.95 | 6.95 | 7.07 | 9.21 |
| C-11 | | | | | 20.97 | 20.86 | 20.86 | 19.32 | 18.87 |
| TAIC | 0.37 | 0.37 | 0.37 | 0.37 | 0.37 | 0.37 | 0.36 | 0.38 | 0.37 |
| BHT | 0.02 | 0.02 | 0.02 | 0.02 | 0.02 | 0.02 | 0.02 | 0.02 | 0.02 |
| Antioxident | 0.02 | 0.02 | 0.02 | 0.02 | 0.02 | 0.02 | 0.02 | 0.02 | 0.02 |
| MgO | 0.36 | 0.35 | 0.35 | 0.35 | 0.35 | 0.36 | 0.35 | 0.36 | 0.35 |
| Adhesion Promoter. | 0.37 | 0.37 | 0.37 | 0.37 | 0.37 | 0.37 | 0.37 | 0.38 | 0.37 |
| Curing Agent | 0.49 | 0.46 | 0.46 | 0.46 | 0.46 | 0.49 | 0.96 | 0.75 | 0.74 |
| Ag Flakes-1 | 52.78 | 53.04 | 53.04 | 53.04 | 53.04 | 52.78 | | 53.64 | 52.40 |
| Ag Flakes-2 | | | | | | | 52.78 | | |

PROPERTIES

| | | | | | | | | | |
|---|---|---|---|---|---|---|---|---|---|
| Vol. Resistivity | 1.4E− | 6.3E− | 1.8E− | 1.9E− | 9.2E− | 7.2E− | 1.1E− | 6.3E− | 8.12E− |
| (ohm-cm) | 03 | 04 | 04 | 04 | 05 | 05 | 04 | 05 | 05 |
| Initial Resistance | 3.71 | 1.21 | 0.64 | 1.92 | 0.24 | 0.29 | 0.28 | 0.38 | 0'37 |
| Initial Resistance | 35.95 | 16.95 | 11.22 | 28.19 | 5.33 | 5.95 | 6.35 | 8.03 | 8.09 |
| (strain) | | | | | | | | | |
| Resistance after 50 | 5.31E+ | 1990 | 132.4 | 9.42E+ | 11.59 | 11.11 | 14.56 | 10.81 | 11.45 |
| cycles of stretch | 07 | | | 07 | | | | | |
| (recovery) | | | | | | | | | |
| Resistance after 50 | Fail | 9604 | 390.6 | Fail | 74.72 | 63.40 | 102.2 | 56.66 | 55.73 |
| cycles of stretch | | | | | | | | | |
| (strain) | | | | | | | | | |
| Initial Resistance | 6.42 | 1.18 | 0,47 | 2.04 | 0.51 | 0.40 | 0.52 | 0.33 | 0.26 |
| (wash) | | | | | | | | | |
| Resistance after 5 | Fail | 3250 | 21.05 | 91.30 | 8.51 | 9.06 | 7.51 | 1.58 | 1.85 |
| cycles of wash | | | | | | | | | |

What is claimed is:

1. A polymer thick film paste composition comprising:
a) conductive powder;
b) an elastomer blend consisting of two or more elastomers at least one of which is a peroxide curable fluoroelastomer; and
c) a solvent blend consisting of at least one solvent in which each of the elastomers of the elastomer blend is individually soluble and at least one solvent in which at least one of the elastomers of the elastomer blend is not individually soluble.

2. The polymer thick film paste composition of claim 1, the elastomer blend consisting of two or more peroxide curable fluoroelastomers.

3. The polymer thick film paste composition of claim 2, wherein the two or more peroxide curable fluoroelastomers are peroxide curable vinylidene fluoride-containing fluoroelestomers.

4. The polymer thick film paste composition of claim 3, wherein the two or more peroxide curable fluoroelastomers are peroxide curable vinylidene fluoride/hexafluoropropylene/tetrafluoroethylene terpolymers.

5. The polymer thick film paste composition of claim 1, the elastomer blend consisting of at least one peroxide curable fluoroelastomer and at least one other elastomer that is not a fluoroelastomer.

6. The polymer thick film paste composition of claim 1, further comprising one or more additives selected from the group consisting of a cross-linking agent, a cross-linking co-agent agent, an antioxidant, an adhesion promoter, a wetting agent, a defoaming agent and a rheology modifier.

7. The polymer thick film paste composition of claim 1, wherein the conductive powder is in the form of silver flakes and wherein the amount of silver flakes is 40-90 wt %, wherein the wt % is based on the total weight of the polymer thick film paste composition.

8. The polymer thick film paste composition of claim 7, wherein the conductive powder is in the form of silver flakes with a sodium oleate/stearate coating.

9. The polymer thick film paste composition of claim 5, wherein the at least one peroxide curable fluoroelastomer is a peroxide curable vinylidene fluoride-containing fluoroelastomer and the at least one other elastomer is an ethylene/methyl acrylate copolymer elastomer and wherein the amount of the at least one peroxide curable fluoroelastomer is 2-30 wt % and the amount of ethylene/methyl acrylate copolymer elastomer is 0.1-10 wt %, wherein the wt % are based on the total weight of the polymer thick film paste composition.

10. The polymer thick film paste composition of claim 9, wherein the at least one peroxide curable fluoroelastomer is a peroxide curable vinylidene fluoride/hexafluoropropylene/tetrafluoroethylene terpolymer.

11. The polymer thick film paste composition of claim 1, wherein the amount of solvent in which each of the elastomers in the elastomer component is individually soluble is 1-20 wt % and the amount of solvent in which at least one of the elastomers is not individually soluble is 5-35 wt %, wherein the wt % are based on the total weight of the polymer thick film composition.

12. The polymer thick film paste composition of claim 1, wherein the at least one solvent in which all of the elastomers of the elastomer blendt are soluble is selected from the group consisting of 4-methyl-2-pentanone, 2,6-dimethyl-4-heptanone, acetone, cyclohexanone, isophorone, N-methyl-2-pyrrolidone and methyl ethyl ketone and at least one solvent in which at least one of the elastomers of the elastomer blend is not soluble is selected from the group consisting of C-11 ketone, dibasic esters, ethylene glycol diacetate, diethylene glycol monoethyl ether acetate and diethylene glycol monobutyl ether acetate.

13. An article comprising a printed conductor formed from the polymer thick film paste composition of claim 1.

14. The article of claim 13, wherein the article is a wearable garment.

15. The article of claim 14, wherein the garment is a fabric garment and the printed conductor is printed directly on the fabric.

16. The article of claim 14, wherein the printed conductor is printed on a substrate which has been subsequently laminated to the garment.

17. The article of claim 13, wherein the article has been thermoformed and subsequently subjected to injection molding.

18. An article comprising a printed conductive adhesive formed from the polymer thick film paste composition of claim 1.

19. The article of claim 18, wherein the article has been thermoformed and subsequently subjected to injection molding.
